(19) United States
(12) Patent Application Publication
(10) Pub. No.: US 2026/0140906 A1
(43) Pub. Date: May 21, 2026

(54) CONFIGURABLE BRIDGE FOR MULTI-CHIP PACKAGE

(71) Applicant: Intel Corporation, Santa Clara, CA (US)

(72) Inventors: Shih Jun CHONG, Pulau Pinang (MY); Kin Yau HOW, Ipoh (MY); Chin Lee KUAN, Bentong (MY); Bok Eng CHEAH, Gelugor (MY); Hooi Leong LIM, Kulim (MY); Chow Yeang TAN, Bayan Lepas (MY)

(21) Appl. No.: 18/954,557

(22) Filed: Nov. 21, 2024

(51) Int. Cl. G06F 13/40; H01L 25/065

(52) U.S. Cl. CPC G06F 13/4027; H10W 90/00; G06F 2213/40; H10W 90/722

(57) ABSTRACT

A device is provided, including a bridge having a first input/output pin and a second input/output pin; a plurality of traces extending horizontally between the first input/output pin and the second input/output pin, the second input/output pin being coupled to a predetermined one or more of the traces; and a first programmable circuit coupled between the first input/output pin and the plurality of traces. The first programmable circuit may include at least one of a demultiplexing section or a multiplexing section. The demultiplexing section may demultiplex a multiplexed signal from the first input/output pin into at least one subset of signals, and route a respective subset of signals to a corresponding one of the traces. The multiplexing section may multiplex the at least one subset of signals from the plurality of traces into the multiplexed signal, and route the multiplexed signal to the first input/output pin.

### BACKGROUND

Current Embedded Multi-die Interconnect Bridge (EMIB) technology presents inherent rework constraints. Specifically, if a fault occurs in the bridge connection, there is limited opportunity for EMIB reworks or repairs, leading to potential product performance impact. In cases of faults where rework or repair is not feasible, the faulty parts may be defeatured. This approach reduces the product margin due to the decreased functionality and value of the compromised components. Another approach is duplication of pathways or connections within the silicon e.g., contingency circuitry block(s) to allow for alternative data transmission path if a fault occurs. This approach may involve silicon footprint and design complexity trade-offs.

In addition, current EMIB technology has silicon footprint limitations for high bandwidth applications and multi-die connections. For example, existing silicon designs require one physical silicon bump per Input/Output signal per die connection, resulting in performance/bandwidth constraints within the same silicon footprint. Large silicon footprint limits the efficiency and scalability of semiconductor devices. To accommodate multiple connections under the one-to-one configuration constraint, current solution requires tighter bump pitch for compact real estate, and increases manufacturing complexity and yield challenges. This solution results in a larger silicon footprint, impacting the overall efficiency and scalability of the device.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A shows a cross-sectional of a device according to an aspect of the present disclosure.

FIG. 1B shows a schematic view of a programmable circuit in the device according to the aspect as shown in FIG. 1A.

FIG. 1C depicts exemplary waveforms of two signals and a multiplexed signal based on the two signals according to an aspect of the present disclosure.

FIG. 2A shows a cross-sectional view of a device according to another aspect of the present disclosure.

FIG. 2B shows a cross-sectional view of a device according to a further aspect of the present disclosure.

FIG. 3A shows a cross-sectional view of a device according to an aspect of the present disclosure.

FIG. 3B shows a top view of the device according to the aspect as shown in FIG. 3A and FIG. 3F.

FIG. 3C shows a schematic view of circuitry interconnections of the device according to the aspect as shown in FIG. 3A.

FIG. 3D shows a schematic view of circuitry interconnection of a first programmable circuit according to the aspect as shown in FIG. 3A.

FIG. 3E shows a schematic view of circuitry interconnection of a second programmable circuit according to the aspect as shown in FIG. 3A.

FIG. 3F shows a cross-sectional view of a device according to a further aspect of the present disclosure.

FIG. 3G shows a schematic view of circuitry interconnections of the device according to the aspect as shown in FIG. 3F.

FIG. 4A shows a cross-sectional view of a device in one-to-many connection according to an aspect of the present disclosure.

FIG. 4B shows a top view of the device according to the aspect as shown in FIG. 4A and FIG. 4G in an aspect.

FIG. 4C shows a top view of the device according to the aspect as shown in FIG. 4A and FIG. 4G in another aspect.

FIG. 4D shows a schematic view of circuitry interconnections of the device as shown in FIG. 4A according to an aspect.

FIG. 4E shows a schematic view of circuitry interconnections of the device as shown in FIG. 4A according to another aspect.

FIG. 4F shows a schematic view of circuitry interconnection of a first programmable circuit according to the aspect as shown in FIG. 4A.

FIG. 4G shows a cross-sectional view of a device in many-to-one connection according to a further aspect of the present disclosure.

FIG. 4H shows a schematic view of circuitry interconnections of the device as shown in FIG. 4G according to an aspect.

FIG. 4I shows a schematic view of circuitry interconnections of the device as shown in FIG. 4G according to another aspect.

FIG. 5 shows a flowchart illustrating a method of forming a device according to an aspect of the present disclosure.

FIG. 6 shows an illustration of a computing device that includes a semiconductor package according to a further aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure addresses the limitations of inherent rework constraints on existing Embedded Multi-die Interconnect Bridge (EMIB) technology. The present disclosure also addresses the silicon footprint limitations for high bandwidth applications and multi-die connections.

In all aspects, the present disclosure generally relates to a device that may include a bridge having a first input/output pin and a second input/output pin; a plurality of traces extending horizontally between the first input/output pin and the second input/output pin, the second input/output pin being coupled to a predetermined one or more of the plurality of traces; and a first programmable circuit coupled between the first input/output pin and the plurality of traces. The first programmable circuit may include at least one of a demultiplexing section or a multiplexing section; wherein the demultiplexing section may be operable to demultiplex a multiplexed signal received from the first input/output pin into at least one subset of signals, and route a respective subset of signals to a corresponding one of the plurality of traces; and wherein the multiplexing section may be operable to multiplex the at least one subset of signals received from the plurality of traces into the multiplexed signal, and route the multiplexed signal to the first input/output pin.

The present disclosure further generally relates to a semiconductor package. The semiconductor package may include a substrate; and a bridge at least partially embedded in the substrate. The bridge may include a first input/output pin; a second input/output pin; a plurality of traces extending horizontally between the first input/output pin and the second input/output pin, the second input/output pin being coupled to a predetermined one or more of the plurality of traces; a first programmable circuit coupled between the first input/output pin and the plurality of traces; a first die on the substrate and coupled to the first input/output pin; and a second die on the substrate and coupled to the second input/output pin. The first programmable circuit may include at least one of a demultiplexing section or a multiplexing section; wherein the demultiplexing section may be operable to demultiplex a multiplexed signal received from the first input/output pin into at least one subset of signals, and route a respective subset of signals to a corresponding one of the plurality of traces; and wherein the multiplexing section may be operable to multiplex the at least one subset of signals received from the plurality of traces into the multiplexed signal, and route the multiplexed signal to the first input/output pin.

The present disclosure generally relates to a method of forming a device. The method may include providing a bridge having a first input/output pin and a second input/output pin; forming a plurality of traces extending horizontally between the first input/output pin and the second input/output pin, and coupling the second input/output pin to a predetermined one or more of the plurality of traces; and coupling a first programmable circuit between the first input/output pin and the plurality of traces. The first programmable circuit may include at least one of a demultiplexing section or a multiplexing section; wherein the demultiplexing section may be operable to demultiplex a multiplexed signal received from the first input/output pin into at least one subset of signals, and route a respective subset of signals to a corresponding one of the plurality of traces; and wherein the multiplexing section may be operable to multiplex the at least one subset of signals received from the plurality of traces into the multiplexed signal, and route the multiplexed signal to the first input/output pin.

Advantages of the present disclosure may include silicon footprint reduction, which slashes bump count on package and silicon, leading to a smaller die size by enabling the multiplexing of two or more signals through a single bump. These signals may then traverse multiple EMIB traces to reach another die, enhancing signal efficiency and reducing costs.

Further advantages of the present disclosure may include package yield improvement. The present disclosure incorporates a defect repair feature, allowing for rerouting if an EMIB trace is defective. This capability significantly elevates EMIB and package yield, ensuring a more reliable product.

Additional advantages of the present disclosure may include increased design flexibility and modularity. The present disclosure allows for a versatile any-to-any die connection by multiplexing numerous signals through a single bump, which may then be distributed across various EMIB traces to multiple dies. This flexibility breaks the limitation of EMIB connectivity to adjacent dies, revolutionizing die-to-die communication (Multiple-Die Interconnection).

To more readily understand and put into practice the aspects of the present semiconductor package, particular aspects will now be described by way of examples and not limitations, and with reference to the figures. For the sake of brevity, duplicate descriptions of features and properties may be omitted.

It should be understood that the terms “on”, “under”, “top”, “bottom”, etc., when used in this description are used for convenience and to aid understanding of relative positions or directions, and not intended to limit the orientation of any device, or structure or any part of any device or structure.

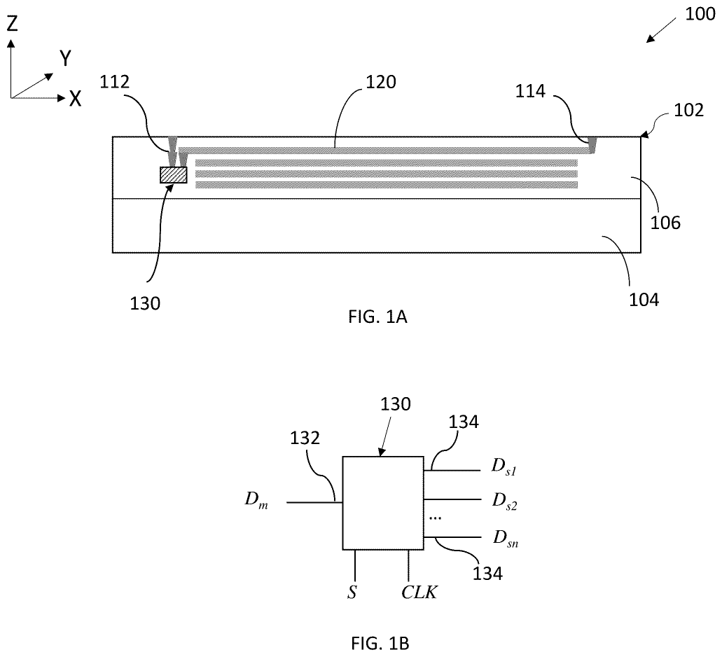

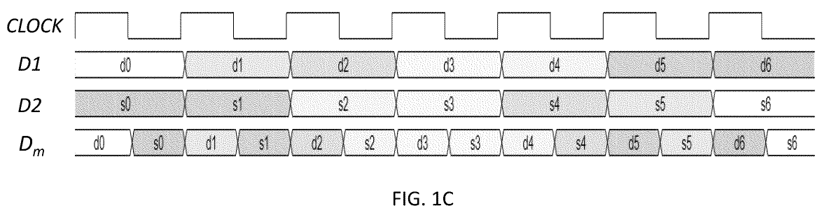

FIG. 1A shows a cross-sectional of a device 100 according to an aspect of the present disclosure. In various aspects, the device 100 may include a bridge 102 having a first input/output pin 112 and a second input/output pin 114. A plurality of traces 120 may extend horizontally between the first input/output pin 112 and the second input/output pin 114, wherein the second input/output pin 114 may be coupled to a predetermined one or more of the plurality of traces 120. A first programmable circuit 130 may be coupled between the first input/output pin 112 and the plurality of traces 120. The first programmable circuit 130 may include at least one of a demultiplexing section or a multiplexing section. The demultiplexing section may be operable to demultiplex a multiplexed signal received from the first input/output pin 112 into at least one subset of signals, and route a respective subset of signals to a corresponding one of the plurality of traces 120. The multiplexing section may be operable to multiplex the at least one subset of signals received from the plurality of traces 120 into the multiplexed signal, and route the multiplexed signal to the first input/output pin 112.

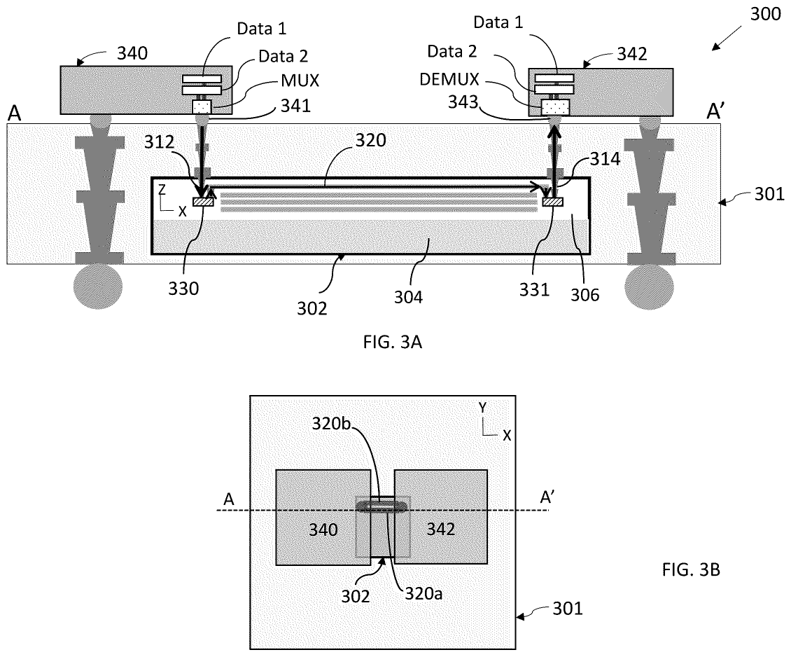

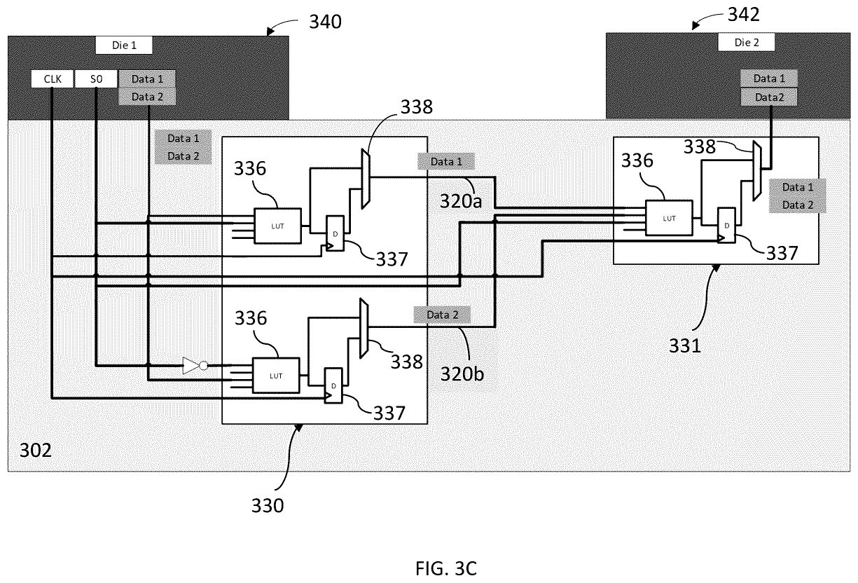

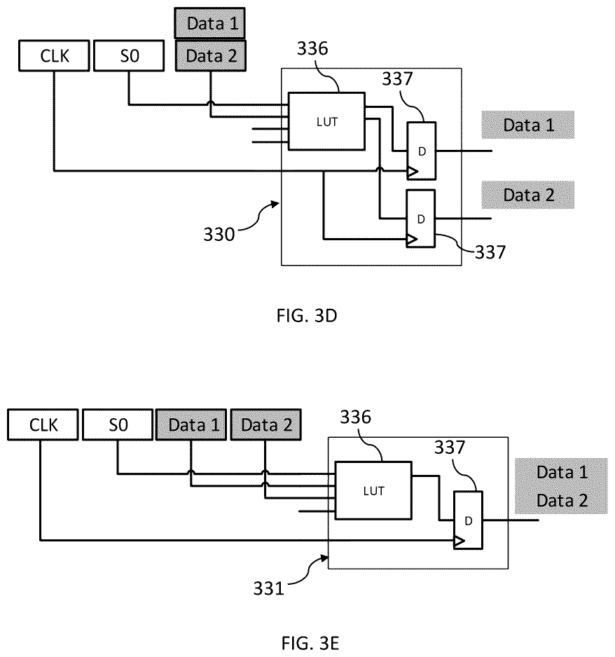

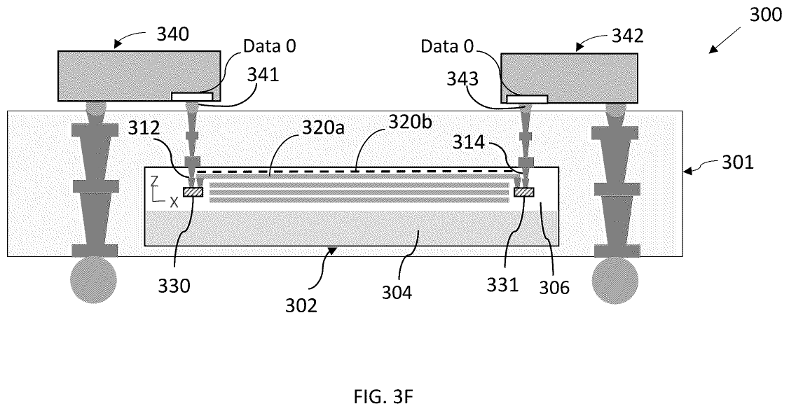

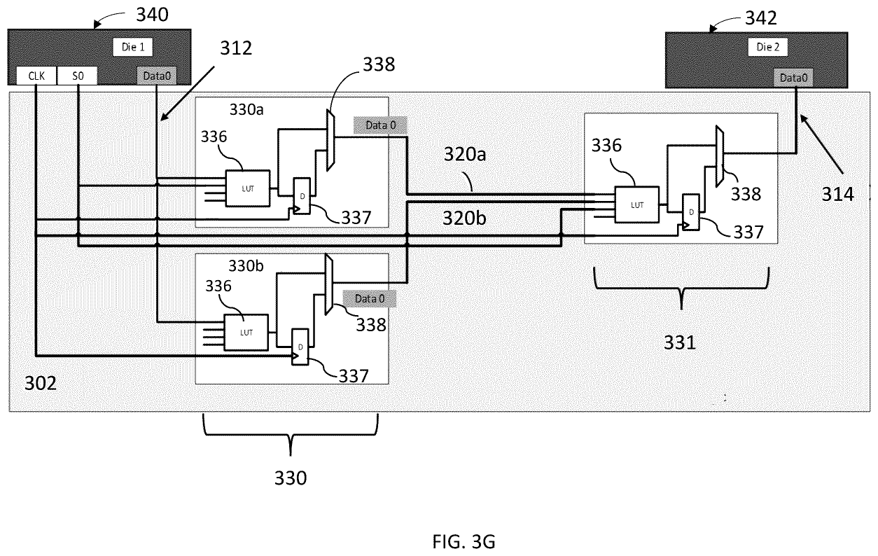

In various aspects, the first input/output pin 112 may be arranged at or close to a first end of the traces 120, and the second input/output pin 114 may be arranged at or close to an opposing second end of the traces 120. The first input/output pin 112 and the second input/output pin 114 may each include one or more interconnects, such as micro vias, for electrical signal transmission. The plurality of traces 120 may be conductive traces, e.g., metal traces, for electrical signal transmission. The plurality of traces 120 may be arranged in Y-axis direction (e.g., as shown in FIG. 3B below). The bridge 102 may further include one or more metal planes or layers (e.g., ground plane, power plane, or other signal planes) arranged under the traces 120 in Z-axis direction.

In various aspects, the first programmable circuit 130 may be arranged in the bridge 102 between the first input/output pin 112 and the plurality of traces 120, to control/route signal transmission between the first input/output pin 112 and the plurality of traces 120. In various aspects, the first programmable circuit 130 may include a programmable look up table (LUT) and a flip-flop. In various aspects, the first programmable circuit 130 may include a programmable look up table (LUT), a flip-flop, and at least one of a multiplexer or a demultiplexer. The LUT may be programmable to route selected signals to selected traces, and such selection of the signals and/or the traces may be varied according to user requirement. The configuration of the programmable LUT may be facilitated through a serial interface, which may include but not limited to protocols such as JTAG, UART, or I2C. This interface may be responsible for controlling the switching and/or signal selection processes within the LUT, ensuring precise and efficient operation. In another aspect, the first programmable circuit 130 may include a processor which may be programmable to perform the multiplexing operation and/or the demultipexing operation.

In various aspects, the first programmable circuit 130 may have the demultiplexing section to receive the multiplexed signal from the first input/output pin 112, separate/demultiplex the multiplexed signal into the at least one subset of signals, and route the respective subset of signals to the corresponding one of the plurality of traces 120. In an aspect, the demultiplexing section may be implemented by at least a programmable LUT, a flip-flop, and a demultiplexer. In another aspect, the demultiplexing section may be implemented by at least a programmable LUT, a flip-flop, and a multiplexer connected to form a demultiplexing circuit. In a further aspect, the demultiplexing section may be implemented by at least a programmable LUT and a flip-flop connected to form a demultiplexing circuit.

In various aspects, the first programmable circuit 130 may have a multiplexing section to receive the at least one subset of signals from the plurality of traces 120, combine/multiplex the at least one subset of signals into the multiplexed signal, and route the multiplexed signal to the first input/output pin 112. In an aspect, the multiplexing section may include a programmable LUT, a flip-flop, and a multiplexer. In another aspect, the multiplexing section may include at least a programmable LUT and a flip-flop connected to form a multiplexing circuit.

FIG. 1B shows a schematic view of the first programmable circuit 130 in the device 100 according to the aspect as shown in FIG. 1A.

As shown in FIG. 1B, the first programmable circuit 130 may have a first terminal 132 coupled to the first input/output pin 112 for receiving and/or outputting the multiplexed signal D_{m.} The multiplexed signal Dₘ may include one or more data signals (D1, D2, D3, . . . ) multiplexed, for example, based on time division multiplexing, and thus may be transmitted via a single input/output pin.

Exemplary waveforms of two data signals D1, D2 and the multiplexed signal Dₘ based on the two data signals D1, D2 are depicted in FIG. 1C according to an aspect of the present disclosure. Each data signal D1, D2 may include or may be divided into multiple frames each having a fixed time slot. After time division multiplexing, the multiplexed signal Dₘ may include multiple frames, in which both frames of the two data signals D1, D2 within the same fixed time slot may be combined. For example, the data signal D1 may include a first frame d0 in the first time slot, and the data signal D2 may include a first frame s0 in the first time slot. The multiplexed signal Dₘ may include a first frame having both d0 and s0 in the first time slot. Accordingly, the two signals D1, D2 may be merged into a single signal which may be transmitted at twice the original frequency of the data signals D1, D2, via a single input/output pin, a single solder bump, or a single trace.

The demultiplexing section of the first programmable circuit 130 may be configured to demultiplex the multiplexed signal Dₘ to generate the at least one subsets of signals (Dₛ₁, Dₛ₂, . . . Dₛₙ) based on a clock signal CLK and a selector signal S. The respective subset of signals may include at least one of the data signals (D1, D2, D3, ...). For example, a first subset of signals Dₛ₁ may include signal D1, or may include a sub-multipexed signal of D1 and D2. In a reverse direction, the multiplexing section of the first programmable circuit 130 may be configured to multiplex the at least one subsets of signals (Dₛ₁, Dₛ₂, . . . Dₛₙ) to generate the multiplexed signal Dₘ based on the clock signal CLK and the selector signal S. Further aspects of the demultiplexing section and the multiplexing section of the first programmable circuit 130 will be described in more details with reference to further figures below.

The first programmable circuit 130 may include a plurality of second terminals 134 coupled to the plurality of traces 120 for outputting and/or receiving the respective subset of signals (Dₛ₁, Dₛ₂, . . . Dₛₙ).

In various aspects, the bridge 102 may include a bridge substrate 104, and a redistribution layer 106 on the bridge substrate. In an aspect, the first programmable circuit 130 may be arranged within the redistribution layer 106 of the bridge 102. In another aspect, the first programmable circuit 130 may be arranged at least partially in the bridge substrate 104 of the bridge 102.

In various aspects, the device 100 may further include a first die (not shown) coupled to the first input/output pin 112 through a first solder bump (not shown), wherein the first input/output pin 112 and the first solder bump may be configured for transmission of the multiplexed signal between the first die and the first programmable circuit 130.

In various aspects, the device 100 may further include a second die (not shown) coupled to the second input/output pin 114 through a second solder bump, wherein the second input/output pin 114 and the second solder bump may be configured for transmission of the respective subset of signals between the second die and the first programmable circuit 130.

According to an aspect, the plurality of traces 120 may include a first trace and a second trace. In an aspect, the second input/output pin 114 may be coupled to one predetermined trace, e.g., the first trace. The subset of signals received from the first trace may be transmitted to the second die through the second input/output pin 114 and the second solder bump. In another aspect, the second input/output pin 114 may be coupled to two or more predetermined traces, e.g., the first trace and the second trace. Two subsets of signals received from the first trace and the second trace may be transmitted to the second die through the second input/output pin 114 and the second solder bump.

According to various aspects, a second programmable circuit (not shown) may be included to couple the second input/output pin 114 to the first trace and the second trace, such that two subsets of signals may be re-multiplexed by the second programmable circuit for transmission via the single second input/output pin 114 and the single second solder bump.

The second programmable circuit may include at least one of a demultiplexing section or a multiplexing section, similar to the first programmable circuit 130 according to various aspects of FIG. 1A and FIG. 1B described above. The multiplexing section of the second programmable circuit may be operable to multiplex a first subset of signals from the first trace and a second subset of signals from the second trace into a re-multiplexed signal, and route the re-multiplexed signal to the second input/output pin 114. The demultiplexing section of the second programmable circuit may be operable to demultiplex the re-multiplexed signal received from the second die into the first subset of signals and the second subset of signals, and route the first subset of signals and the second subset of signals to the first trace and the second trace, respectively.

Examples of the first die may include but are not limited to a central processing unit (CPU), or a system-on-chip (SOC). Examples of the second die may include but are not limited to a graphic processing unit (GPU), a neural network processing unit (NPU), a tensor processing unit (TPU), a graphic processing unit (GPU), or a high-bandwidth memory (HBM). In various aspects, the first die may be coupled to the second die through the bridge 102, wherein the first die and the second die may be arranged on a substrate, and the bridge 102 may be at least partially embedded in the substrate.

In various aspects, the bridge 102 may further include a third input/output pin (not shown) coupled to another predetermined one or more of the plurality of traces 120.

In an aspect, the plurality of traces 120 may include a first trace and a second trace. The second input/output pin 114 may be coupled to the first trace, and the third input/output pin may be coupled to the second trace.

A third die may be coupled to the third input/output pin through a third solder bump, wherein the third input/output pin and the third solder bump may be configured for transmission of the respective subset of signals between the third die and the first programmable circuit 130.

In other words, the second die may receive the respective subset of signals transmitted from the first trace via the second input/output pin 114, and the third die may receive the respective subset of signals transmitted from the second trace via the third input/output pin. Alternatively or Additionally, the second die may transmit the respective subset of signals to the first trace via the second input/output pin 114, and the third die may transmit the respective subset of signals to the second trace via the third input/output pin.

Examples of the third die may include but are not limited to a graphic processing unit (GPU), a neural network processing unit (NPU), a tensor processing unit (TPU), a graphic processing unit (GPU), or a high-bandwidth memory (HBM). In various aspects, the first die may be coupled to the second die and the third die through the bridge 102.

In a further aspect, the bridge 102 may include a third programmable circuit (not shown) coupling the third input/output pin to the predetermined one or more traces, e.g., two traces, such that two subsets of signals may be re-multiplexed by the third programmable circuit for transmission via the single third input/output pin and the single third solder bump.

The third programmable circuit may include at least one of a demultiplexing section or a multiplexing section, similar to the first programmable circuit 130 according to various aspects of FIG. 1A and FIG. 1B described above. The multiplexing section of the third programmable circuit may be operable to multiplex the respective subset of signals from the predetermined one or more traces into a re-multiplexed signal, and route the re-multiplexed signal to the third input/output pin. The demultiplexing section of the third programmable circuit may be operable to demultiplex the re-multiplexed signal received from the third die into the respective subset of signals, and route the respective subset of signals to the predetermined one or more traces.

The present disclosure may provide an electronic package with a configurable bridge for improved reliability and device miniaturization. According to various aspects, at least a first programmable circuit 130 may be provided in the bridge to control or configure the signal routing among the input/output pins, and accordingly, to control or configure the signal routing among a plurality of dies.

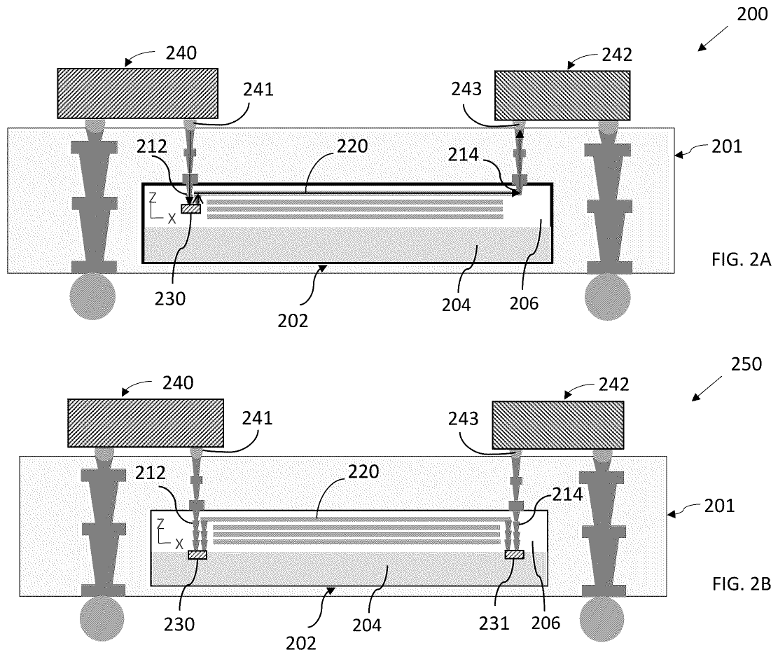

FIG. 2A shows a cross-sectional view of a device 200 according to another aspect of the present disclosure. FIG. 2B shows a cross-sectional view of a device 250 according to a further aspect of the present disclosure.

Many of the aspects of the device 200, 250 are the same or similar to those of the device 100. For the sake of brevity, duplicate descriptions of features and properties are omitted. Accordingly, it will be understood that the descriptions of any feature and/or property relating to FIG. 2A and FIG. 2B that are the same or similar to a feature and/or property in FIGS. 1A to 1C will have those descriptions be applicable herein below as well.

Similar to the device 100, the device 200, 250 may include a bridge 202 having a first input/output pin 212 and a second input/output pin 214. A plurality of traces 220 may extend horizontally between the first input/output pin 212 and the second input/output pin 214, wherein the second input/output pin 214 may be coupled to a predetermined one or more of the plurality of traces 220. A first programmable circuit 230 may be coupled between the first input/output pin 212 and the plurality of traces 220. The first programmable circuit 230 may include at least one of a demultiplexing section or a multiplexing section. The demultiplexing section may be operable to demultiplex a multiplexed signal received from the first input/output pin 212 into at least one subset of signals, and route a respective subset of signals to a corresponding one of the plurality of traces 220. The multiplexing section may be operable to multiplex the at least one subset of signals received from the plurality of traces 220 into the multiplexed signal, and route the multiplexed signal to the first input/output pin 212.

The first input/output pin 212 may be arranged at or close to a first end of the traces 220, and the second input/output pin 214 may be arranged at or close to an opposing second end of the traces 220. The first input/output pin 212 and the second input/output pin 214 may each include one or more interconnects, such as micro vias, for electrical signal transmission. The plurality of traces 220 may be conductive traces, e.g., metal traces, for electrical signal transmission.

In various aspects, the first programmable circuit 230 may be arranged in the bridge 202 between the first input/output pin 212 and the plurality of traces 220, to control/route signal transmission between the first input/output pin 212 and the plurality of traces 220. In various aspects, the first programmable circuit 230 may include a programmable look up table (LUT) and a flip-flop. In various aspects, the first programmable circuit 230 may include a programmable look up table (LUT), a flip-flop, and at least one of a multiplexer or a demultiplexer. The LUT may be programmable to route selected signals to selected traces, and such selection of the signals and/or the traces may be varied according to user requirement. The configuration of the programmable LUT may be facilitated through a serial interface, which may include but not limited to protocols such as JTAG, UART, or I2C, and which may be responsible for controlling the switching and/or signal selection processes within the LUT. In another aspect, the first programmable circuit 230 may include a processor which may be programmable to perform the multiplexing operation and/or the demultipexing operation.

In various aspects, the first programmable circuit 230 may have the demultiplexing section to receive the multiplexed signal from the first input/output pin 212, separate/demultiplex the multiplexed signal into the at least one subset of signals, and route the respective subset of signals to the corresponding one of the plurality of traces 220. In an aspect, the demultiplexing section may be implemented by at least a programmable LUT, a flip-flop, and a demultiplexer. In another aspect, the demultiplexing section may be implemented by at least a programmable LUT, a flip-flop, and a multiplexer connected to form a demultiplexing circuit. In a further aspect, the demultiplexing section may be implemented by at least a programmable LUT and a flip-flop connected to form a demultiplexing circuit.

In various aspects, the first programmable circuit 230 may have a multiplexing section to receive the at least one subset of signals from the plurality of traces 220, combine/multiplex the at least one subset of signals into the multiplexed signal, and route the multiplexed signal to the first input/output pin 212. In an aspect, the multiplexing section may include a programmable LUT, a flip-flop, and a multiplexer.

The first programmable circuit 230 may be similar to the first programmable circuit 130 in the aspects shown in FIG. 1B. Similarly, the first programmable circuit 230 may have a first terminal coupled to the first input/output pin 212 for receiving and/or outputting the multiplexed signal D_{m.} The multiplexed signal Dₘ may include one or more data signals (D1, D2, D3, . . . ) multiplexed, for example, based on time division multiplexing, and thus may be transmitted via a single input/output pin.

The demultiplexing section of the first programmable circuit 230 may be configured to demultiplex the multiplexed signal Dₘ to generate the at least one subsets of signals (Dₛ₁, Dₛ₂, . . . Dₛₙ) based on a clock signal CLK and a selector signal S. The respective subset of signals may include at least one of the data signals (D1, D2, D3, . . . ). For example, a first subset of signals Dₛ₁ may include signal D1, or may include a sub-multipexed signal of D1 and D2. In a reverse direction, the multiplexing section of the first programmable circuit 230 may be configured to multiplex the at least one subsets of signals (Dₛ₁, Dₛ₂, . . . Dₛₙ) to generate the multiplexed signal Dₘ based on the clock signal CLK and the selector signal S. Further aspects of the demultiplexing section and the multiplexing section of the first programmable circuit 230 will be described in more details with reference to further figures below.

Similar to the first programmable circuit 130, the first programmable circuit 230 may include a plurality of second terminals coupled to the plurality of traces 220 for outputting and/or receiving the respective subset of signals (Dₛ₁, Dₛ₂, . . . Dₛₙ).

In various aspects as shown in FIG. 2A and FIG. 2B, the bridge 202 may include a bridge substrate 204, and a redistribution layer (RDL) 206 on the bridge substrate 204. The bridge substrate 204 may include a silicon substrate, a glass substrate, a ceramic substrate, or an organic substrate. The plurality of traces 220, the first input/output pin 212 and the second input/output pin 214 may be disposed within the redistribution layer 206.

In an aspect as shown in FIG. 2A, the first programmable circuit 230 may be arranged within the redistribution layer 206 of the bridge 202. In another aspect as shown in FIG. 2B, the first programmable circuit 230 may be arranged at least partially in the bridge substrate 204 of the bridge 202.

In various aspects as shown in FIG. 2A and FIG. 2B, the device 200, 250 may further include a first die 240 coupled to the first input/output pin 212 through a first solder bump 241, wherein the first input/output pin 212 and the first solder bump 241 may be configured for transmission of the multiplexed signal between the first die 240 and the first programmable circuit 230. Examples of the first die 240 may include but are not limited to a central processing unit (CPU), or a system-on-chip (SOC).

In various aspects as shown in FIG. 2A and FIG. 2B, the device 200, 250 may further include a second die 242 coupled to the second input/output pin 214 through a second solder bump 243, wherein the second input/output pin 214 and the second solder bump 243 may be configured for transmission of the respective subset of signals between the second die 242 and the first programmable circuit 230. Examples of the second die 242 may include but are not limited to a graphic processing unit (GPU), a neural network processing unit (NPU), a tensor processing unit (TPU), a graphic processing unit (GPU), or a high-bandwidth memory (HBM).

In various aspects, the device 200, 250 may further include a substrate 201, wherein the bridge 202 may be at least partially embedded within the substrate 201. The first die 240 and the second die 242 may be attached on the top surface of the substrate 201, and may be coupled to each other through the bridge 202. The substrate 201 may further include a plurality of interconnects and/or metal planes embedded therein and spaced apart by a dielectric layer. In an aspect, the substrate 201 may be a package substrate, or may be a silicon interposer. In another aspect, the substrate 201 may be a printed circuit board. In various aspects, the substrate 201 may be coupled to a further printed circuit board.

According to an aspect, the plurality of traces 220 may include a first trace and a second trace. In an aspect, the second input/output pin 214 may be coupled to one predetermined trace, e.g., the first trace. The subset of signals received from the first trace may be transmitted to the second die 242 through the second input/output pin 214 and the second solder bump 243. In another aspect, the second input/output pin 214 may be coupled to two or more predetermined traces, e.g., the first trace and the second trace (shown in FIG. 3B and FIG. 3F below). Two subsets of signals received from the first trace and the second trace may be transmitted to the second die 242 through the second input/output pin 214 and the second solder bump 243.

According to various aspects as shown in FIG. 2B, a second programmable circuit 231 may be included to couple the second input/output pin 214 to the first trace and the second trace (shown in FIG. 3B and FIG. 3F), such that two subsets of signals may be re-multiplexed by the second programmable circuit 231 for transmission via the single second input/output pin 214 and the single second solder bump 243. The second programmable circuit 231 may be arranged within the redistribution layer 206, or may be at least partially embedded in the bridge substrate 204.

The first programmable circuit 230 may be arranged along a first edge of the substrate, e.g., close to the first input/output pin 212 and a first end of the traces 220. The second programmable circuit 231 may be arranged along an opposing second edge of the substrate, e.g., close to the second input/output pin 214 and an opposing second end of the traces 220. The first programmable circuit 230 and the second programmable circuit 231 may be coupled through the plurality of traces 220.

In an aspect, the first and the second programmable circuit 230, 231 may be configured within the bridge substrate 204, e.g., through doping and metallization process. In another aspect, the first and the second programmable circuit 230, 231 may be discrete components embedded in the bridge substrate 204 or the redistribution layer 206.

The second programmable circuit 231 may include at least one of a demultiplexing section or a multiplexing section, similar to the first programmable circuit 130, 230 according to various aspects described above. The multiplexing section of the second programmable circuit 231 may be operable to multiplex a first subset of signals from the first trace and a second subset of signals from the second trace into a re-multiplexed signal, and route the re-multiplexed signal to the second input/output pin 214. The demultiplexing section of the second programmable circuit 231 may be operable to demultiplex the re-multiplexed signal received from the second die 242 into the first subset of signals and the second subset of signals, and route the first subset of signals and the second subset of signals to the first trace and the second trace, respectively.

FIG. 3A shows a cross-sectional view of a device 300 for solder bump count reduction and silicon footprint miniaturization according to an aspect of the present disclosure. FIG. 3F shows a cross-sectional view of the device 300 for defect remedy according to a further aspect of the present disclosure. FIG. 3B shows a top view of the device 300 according to the aspect as shown in FIG. 3A and FIG. 3F.

Many of the aspects of the device 300 are the same or similar to those of the device 100, 200, 250. For the sake of brevity, duplicate descriptions of features and properties are omitted. Accordingly, it will be understood that the descriptions of any feature and/or property relating to FIG. 3A and FIG. 3F that are the same or similar to a feature and/or property in FIGS. 1A-1C and 2A-2B will have those descriptions be applicable herein below as well.

Similar to the device 100, 200, 250, the device 300 may include a bridge 302 having a first input/output pin 312 and a second input/output pin 314. A plurality of traces 320 may extend horizontally between the first input/output pin 312 and the second input/output pin 314, wherein the second input/output pin 314 may be coupled to a predetermined one or more of the plurality of traces 320. A first programmable circuit 330 may be coupled between the first input/output pin 312 and the plurality of traces 320. The first programmable circuit 330 may include at least one of a demultiplexing section or a multiplexing section. The demultiplexing section may be operable to demultiplex a multiplexed signal received from the first input/output pin 312 into at least one subset of signals, and route a respective subset of signals to a corresponding one of the plurality of traces 320. The multiplexing section may be operable to multiplex the at least one subset of signals received from the plurality of traces 320 into the multiplexed signal, and route the multiplexed signal to the first input/output pin 312.

In various aspects as shown in FIG. 3A and FIG. 3F, the bridge 302 may include a bridge substrate 304, and a redistribution layer (RDL) 306 on the bridge substrate 304. The plurality of traces 320, the first input/output pin 312 and the second input/output pin 314 may be disposed within the redistribution layer 306.

According to various aspects as shown in FIG. 3A and FIG. 3F, a second programmable circuit 331 may be included to couple the second input/output pin 314 to the predetermined one or more traces 320, for signal routing therebetween.

In the aspect as shown in FIG. 3A and FIG. 3F, the first programmable circuit 330 and the second programmable circuit 331 may be arranged within the redistribution layer 306 of the bridge 302. The first programmable circuit 330 and the second programmable circuit 331 may be coupled to each other through the plurality of traces 320.

Similar to the device 200, 250, the device 300 may further include a first die 340 coupled to the first input/output pin 312 through a first solder bump 341, wherein the first input/output pin 312 and the first solder bump 341 may be configured for transmission of the multiplexed signal between the first die 340 and the first programmable circuit 330.

Similar to the device 200, 250, the device 300 may further include a second die 342 coupled to the second input/output pin 314 through a second solder bump 343, wherein the second input/output pin 314 and the second solder bump 343 may be configured for transmission of the multiplexed signal between the second die 342 and the second programmable circuit 331.

Similarly, the device 300 may further include a substrate 301, wherein the bridge 302 may be at least partially embedded within the substrate 301. The first die 340 and the second die 342 may be attached on the top surface of the substrate 301, and may be coupled to each other through the bridge 302. The substrate 301 may be a package substrate, a silicon interposer, or a printed circuit board.

According to an aspect as shown in FIG. 3B and FIG. 3F, the plurality of traces 320 may include a first trace 320a and a second trace 320b. The second trace 320b may be arranged in the Y-axis direction as shown in the top view of FIG. 3B, and may be invisible from the cross-sectional view of FIG. 3A and is shown as dotted line in FIG. 3F. In an aspect, the second input/output pin 314 may be coupled to two or more predetermined traces, e.g., the first trace 320a and the second trace 320b, through the second programmable circuit 331. Accordingly, two subsets of signals received from the first trace 320a and the second trace 320b may be re-multiplexed by the second programmable circuit 331 for transmission to the second die 342, via the single second input/output pin 314 and the single second solder bump 343.

In an aspect shown in FIG. 3A, two signals (Data 1, Data 2) may be multiplexed by a multiplexer MUX within the first die (Die 1) 340 for silicon footprint miniaturization. These signals may be transmitted through a single bump 341, instead of two dedicated bumps for two signals in a conventional approach, to the second die (Die 2) 342 through the bridge 302. Upon reaching the bridge 302, the multiplexed signal may be de-multiplexed by the first programmable circuit 330 into two separate signals (Data 1, Data 2) and routed to two separate traces 320a, 320b to manage the timing budgets effectively. The two separate signals (Data 1, Data 2) may be subsequently re-multiplexed by the second programmable circuit 331 before being sent to the second die (Die 2) 342 via the second bump 343. Within the second die (Die 2) 342, the re-multiplexed signal may be de-multiplexed back into their original forms (Data 1, Data 2) by a demultiplexer DEMUX. Through the configurable bridge 302 with the first and the second programmable circuits 330, 331, the device 300 according to the aspects of FIG. 3A may reduce the overall bump count from two to one in both Die 1 and Die 2.

FIG. 3C shows a schematic view of circuitry interconnections of the device 300 according to the aspect as shown in FIG. 3A.

In various aspects shown in FIG. 3C, the first programmable circuit 330 may include the demultiplexing section to receive the multiplexed signal from the first die 340, demultiplex the multiplexed signal into the separate signals (Data 1, Data 2), and route the respective signals (Data 1, Data 2) to the first trace 320a and the second trace 320b, respectively. The first programmable circuit 330 may be similar to the first programmable circuit 130 in the aspects shown in FIG. 1B. Similarly, the first programmable circuit 330 may have a first terminal coupled to the first die 340 for receiving the multiplexed signal, and may include a plurality of second terminals coupled to the traces 320a, 320b for outputting the respective signals (Data 1, Data 2).

In an aspect, the demultiplexing section may be implemented by at least a programmable LUT 336, a flip-flop 337, and a multiplexer 338 connected to form a demultiplexing circuit. In an example as shown in FIG. 3C, the demultiplexing section of the first programmable circuit 330 may include two groups of programmable LUTs 336, flip-flops 337 and multiplexers 338, to route two signals (Data 1, Data 2) to the first trace 320a and the second trace 320b, respectively. In an aspect, the LUT 336 may be coupled to the multiplexed signal and a selector signal (S0). The flip-flops 337 may be coupled to a clock source. The selector signal (S0) and the clock source may be provided by the first die 340 or the second die 342. In another aspect, the demultiplexing section may be implemented by at least a programmable LUT 336, a flip-flop 337, and a demultiplexer (not shown).

In a further aspect, the demultiplexing section may be implemented by at least a programmable LUT 336 and a flip-flop 337 connected to form a demultiplexing circuit. FIG. 3D shows a schematic view of circuitry interconnection of the first programmable circuit 330. In the example as shown in FIG. 3D, the demultiplexing section of the first programmable circuit 330 may include a programmable LUTs 336 and a plurality of flip-flops 337 to determine and output the two signals (Data 1, Data 2) to the second terminals of the first programmable circuit 330. It is understood that the demultiplexing section may be implemented in any suitable combination of circuit components or may be implemented in a processor in various aspects to perform the demultiplexing operations as described above.

In various aspects shown in FIG. 3C, the second programmable circuit 331 may include the multiplexing section operable to re-multiplex the respective signals (Data 1, Data 2) from the first trace 320a and the second trace 320b into a re-multiplexed signal, and route the re-multiplexed signal to the second die 342 through the second input/output pin 314.

In an aspect, the multiplexing section of the second programmable circuit 331 may be implemented by at least a programmable LUT 336, a flip-flop 337, and a multiplexer 338. In an example as shown in FIG. 3C, the multiplexing section of the second programmable circuit 331 may include a group of programmable LUT 336, flip-flop 337 and multiplexer 338, to route the re-multiplexed signal to the second die 342. In an aspect, the LUT 336 may be coupled to the respective signals (Data 1, Data 2) and the selector signal (S0). The flip-flop 337 may be coupled to the clock source.

In another aspect, the multiplexing section of the second programmable circuit 331 may be implemented by at least a programmable LUT 336 and a flip-flop 337 connected to form a multiplexing circuit. FIG. 3E shows a schematic view of circuitry interconnection of the second programmable circuit 331. In the example as shown in FIG. 3E, the multiplexing section of the second programmable circuit 331 may include a programmable LUTs 336 and a flip-flop 337 to re-multiplex the respective signals (Data 1, Data 2) into a re-multiplexed signal, and route the re-multiplexed signal to the second die 342. It is understood that the multiplexing section may be implemented in any suitable combination of circuit components or may be implemented in a processor in various aspects to perform the multiplexing operations as described above.

In another aspect shown in FIG. 3F, the device 300 may be applied for defect remedy when a trace is defective, e.g., due to manufacturing or over a certain span of usage. An input signal received from the first die 340 may include one data signal (Data 0). The signal path, e.g., a unidirectional universal chiplet interconnect express (UCIe) signal with operating data rate ranging from 2 Gbps to 32 Gbps from the first die (Die 1) 340 may be branched into two identical data signals (Data 0, Data 0) to the first trace 320a and the second trace 320b. This setup of the first programmable circuit 330 and the second programmable circuit 331 may allow the selection of either the first trace 320a or the second trace 320b to be connected to the second bump 343 of the second die 342. The capability to switch paths via the programmable circuits 330, 331 may ensure continued connectivity, even if one trace e.g., the second trace 320b is compromised.

FIG. 3G shows a schematic view of circuitry interconnections of the device 300 according to the aspect as shown in FIG. 3F.

In various aspects shown in FIG. 3G, the first programmable circuit 330 may include the demultiplexing section to receive the input signal (Data 0) from the first die 340. In various aspects, the demultiplexing section of the first programmable circuits 330 may include a first demultiplexing circuit 330a to receive the input signal from the first die 340. In various aspects, the demultiplexing section of the first programmable circuits 330 may further include a second demultiplexing circuit 330b to receive the input signal from the first die 340. In this way, the input signal may be duplicated (or branched) into two identical signals (Data 0, Data 0), and the respective signals (Data 0, Data 0) may be routed to the first trace 320a and the second trace 320b, respectively. The first programmable circuit 330 in FIG. 3G may be similar to the first programmable circuit 130 in the aspects shown in FIG. 1B. Similarly, the first programmable circuit 330 may have a first terminal coupled to the first input/output pin 312 for receiving the input signal from the first die 340, and may include a plurality of second terminals coupled to the traces 320a, 320b for outputting the respective signals (Data 0, Data 0). In this context, the input signal may correspond to the multiplexed signal Dm of FIG. 1B including only one data signal (Data 0). The first subset of signals Dₛ₁ and the second subset of signals Dₛ₂ of FIG. 1B may each include the same data signal (Data 0). According to the aspect of FIG. 3G, the data signal (Data 0) may still be transmitted through the first trace 320a, if the second trace 320b is compromised.

In an aspect according to FIG. 3G, the demultiplexing section may be implemented by at least a programmable LUT 336, a flip-flop 337, and a multiplexer 338 connected to form a demultiplexing circuit. In an example as shown in FIG. 3G, the demultiplexing section of the first programmable circuit 330 may include two groups of programmable LUTs 336, flip-flops 337 and multiplexers 338. In an aspect, the first group of programmable LUTs 336, flip-flops 337 and multiplexers 338 may form the first demultiplexing circuit 330a, which may be coupled to the first input/output pin 312 and the first trace 320a. The second group of programmable LUTs 336, flip-flops 337 and multiplexers 338 may form the second demultiplexing circuit 330 b, which may be coupled to the first input/output pin 312 and the second trace 320b. In an aspect, the respective LUT 336 may be coupled to the input signal (Data 0) and a selector signal (S0). The flip-flops 337 may be coupled to a clock source. The selector signal (S0) and the clock source may be provided by the first die 340 or the second die 342. It is understood that the demultiplexing section may be implemented in any suitable combination of circuit components (in one example, by a combination of at least a programmable LUT, a flip-flop, and a demultiplexer; and in another example, by a combination of at least a programmable LUT and a flip-flop similar to the circuitry of FIG. 3D), or may be implemented in a processor in various aspects to perform the demultiplexing operations (e.g., signal replication or branching operations) as described above.

In various aspects shown in FIG. 3G, the second programmable circuit 331 may include the multiplexing section operable to select the respective signals (Data 0, Data 0) from the first trace 320a and the second trace 320b for transmission to the second die 342. The second programmable circuit 331 may route the input signal to the second die 342 through the second input/output pin 314.

In an aspect shown in FIG. 3G, the multiplexing section of the second programmable circuit 331 that regulates the signal selection may be implemented by at least a programmable LUT 336, a flip-flop 337, and a multiplexer 338. In an example as shown in FIG. 3G, the multiplexing section of the second programmable circuit 332 may include a group of programmable LUT 336, flip-flop 337 and multiplexer 338, to route the input signal to the second die 342. In an aspect, the LUT 336 may be coupled to the respective signals (Data 0, Data 0) and the selector signal (S0). The flip-flop 337 may be coupled to the clock source. It is understood that the multiplexing section may be implemented in any suitable combination of circuit components (e.g., by a combination of at least a programmable LUT and a flip-flop similar to the circuitry shown in FIG. 3E), or may be implemented in a processor in various aspects to perform the signal selection operations as described above.

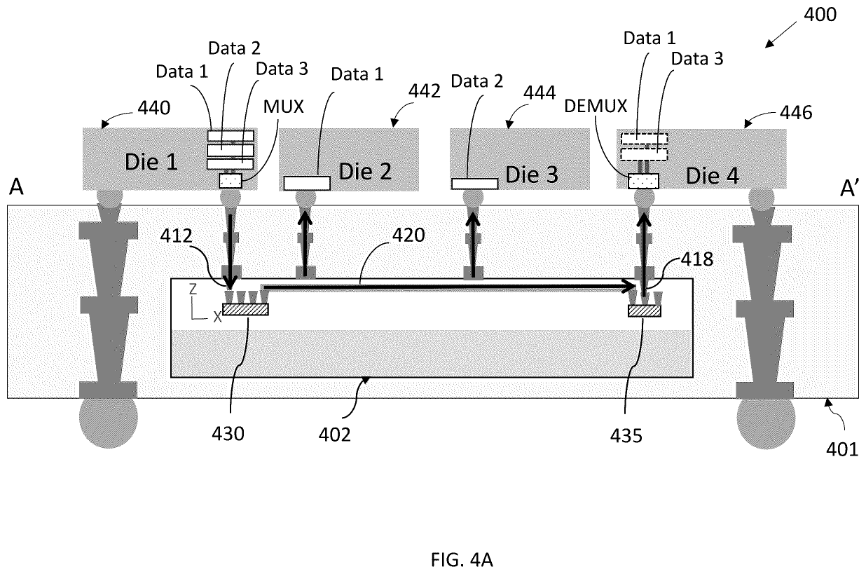

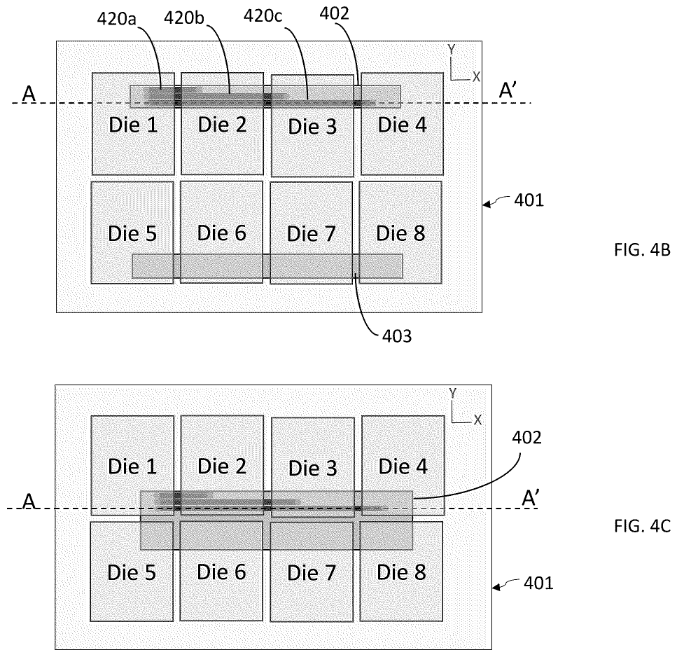

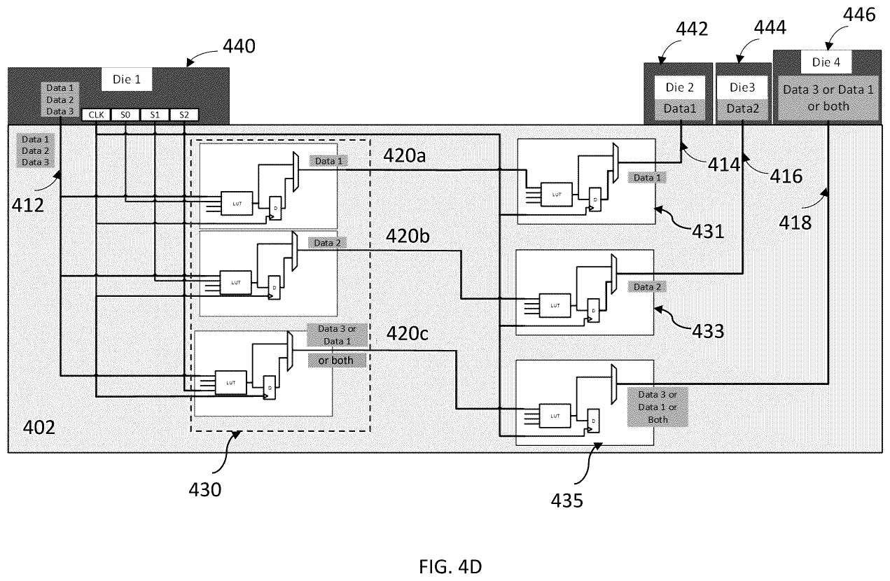

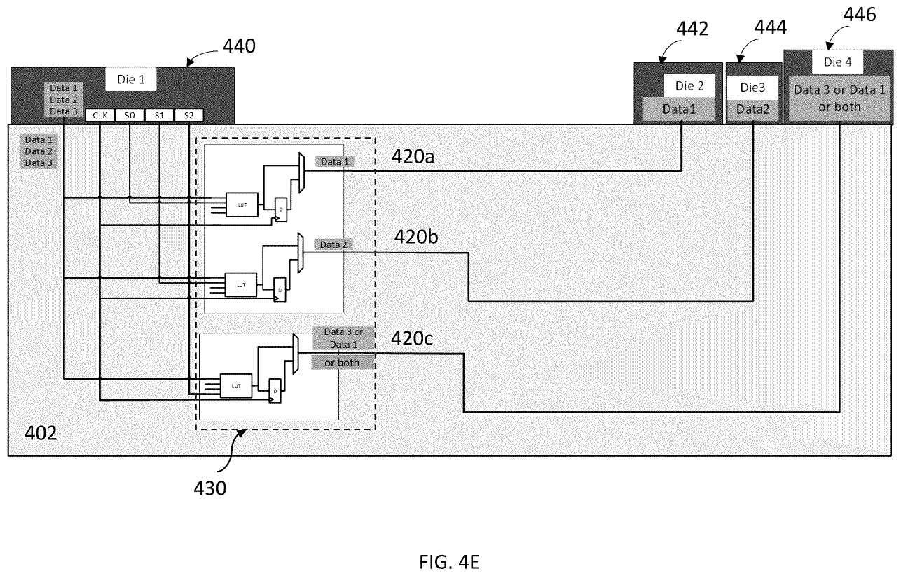

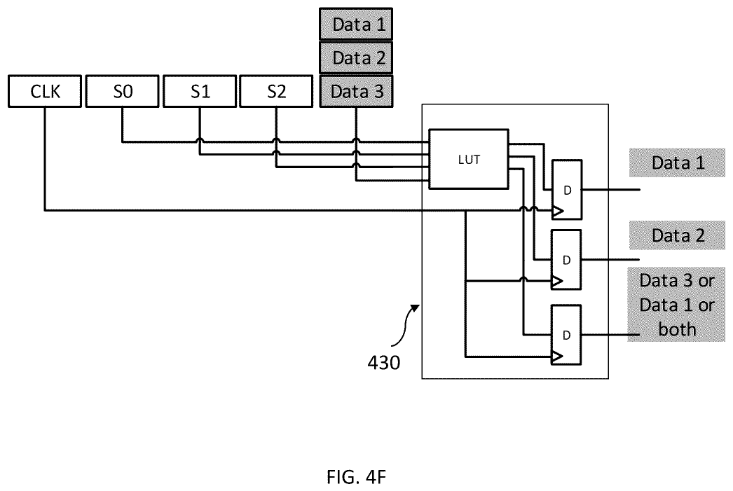

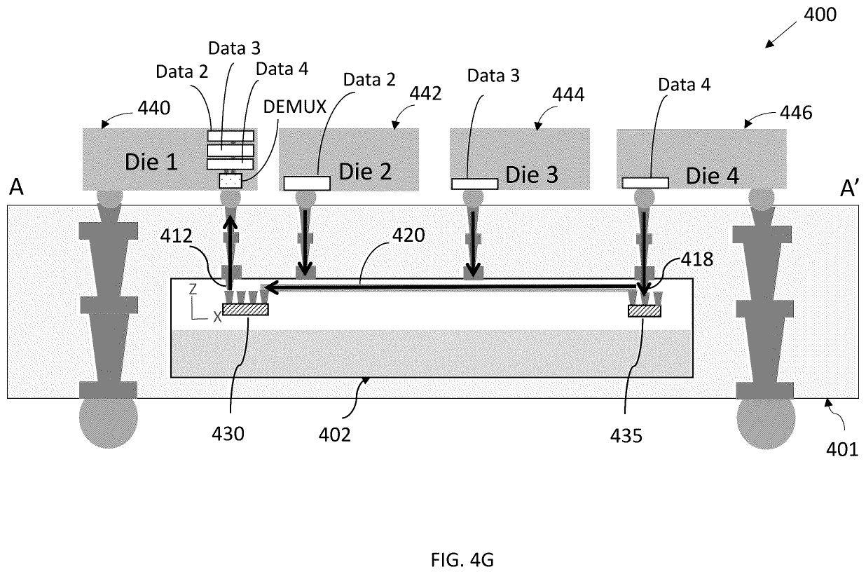

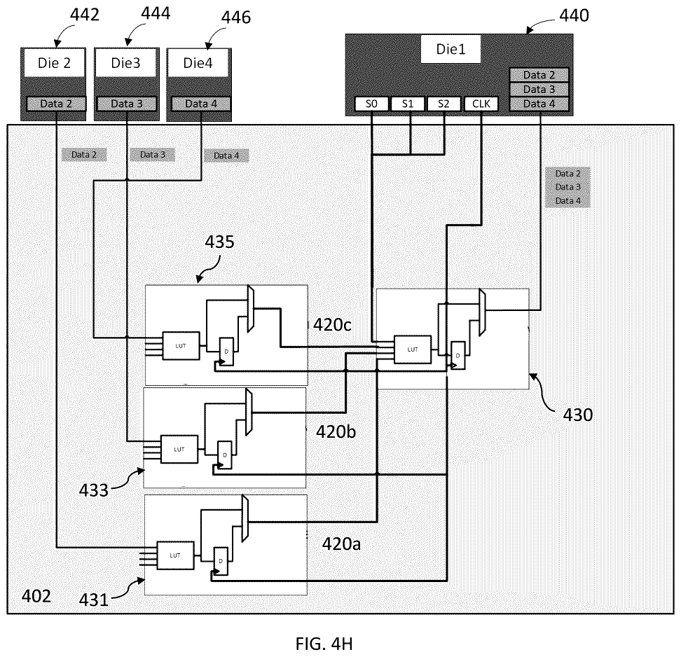

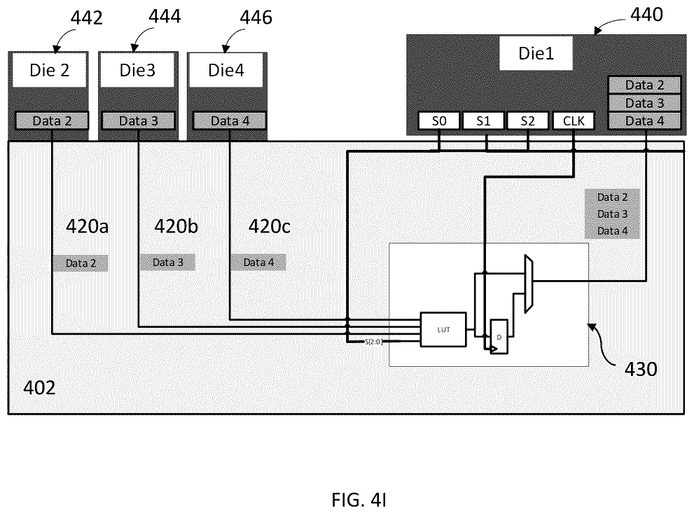

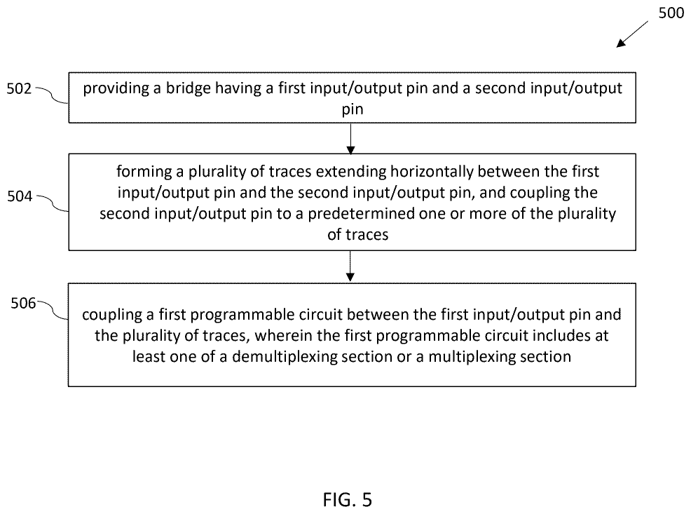

FIG. 4A shows a cross-sectional view of a device 400 applied for one-to-many die interconnection according to an aspect of the present disclosure. FIG. 4G shows a cross-sectional view of the device 400 applied for many-to-one die interconnection according to a further aspect of the present disclosure. FIG. 4B and FIG. 4C show a top view of the device 400 according to various aspects as shown in FIG. 4A and FIG. 4G. A schematic view of circuitry interconnections of the device 400 according to the aspect of FIG. 4A is shown in FIGS. 4D-4E. A schematic view of circuitry interconnections of the device 400 according to the aspect of FIG. 4G is shown in FIGS. 4H-4I. It is understood that the device 400 may be applied for either one or both of one-to-many die interconnection and many-to-one die interconnection for unidirectional or bidirectional data transmission.

Many of the aspects of the device 400 are the same or similar to those of the device 100, 200, 250, 300. For the sake of brevity, duplicate descriptions of features and properties are omitted. Accordingly, it will be understood that the descriptions of any feature and/or property relating to FIGS. 4A-4I that are the same or similar to a feature and/or property in FIGS. 1A-1C, 2A-2B and 3A-3G will have those descriptions be applicable herein below as well.

Similar to the device 100, 200, 250, 300, the device 400 of FIG. 4A and FIG. 4G may include a bridge 402 with a plurality of traces 420 extending horizontally in the bridge 402. The device 400 may further include a substrate 401, wherein the bridge 402 may be at least partially embedded within the substrate 401.

According to various aspects of FIG. 4A and FIG. 4G, the device 400 may include a plurality of input/output pins in the bridge 402, and may include a plurality of dies disposed on the substrate 401 and coupled to the corresponding input/output pins. In the aspects as shown in FIG. 4A and FIG. 4G, four dies are included and coupled to four input/output pins, respectively. It is understood that the device 400 may include any other number of dies and corresponding input/output pins in various other aspects.

In the aspects as shown in FIG. 4A and FIG. 4G, the device 400 may include a first input/output pin 412 coupled to a first die (Die 1) 440, a second input/output pin 414 (shown in FIG. 4D) coupled to a second die (Die 2) 442, a third input/output pin 416 (shown in FIG. 4D) coupled to a third die (Die 3) 444, and a fourth input/output pin 418 coupled to a fourth die (Die 4) 446.

The bridge 402 may be coupled to the plurality of dies for signal transmission therebetween. In an aspect shown in the top view of FIG. 4B, the bridge 402 may be coupled to the four dies (Die 1, Die 2, Die 3, Die 4) arranged in a row. A further bridge 403 similar to the bridge 402 may be provided to couple further dies (Die 5, Die 6, Die 7, Die 8) arranged in another row. In another aspect shown in the top view of FIG. 4C, the bridge 402 may be shared and coupled to all dies (Die 1 to Die 8).

As shown in FIGS. 4A and 4G, the first die 440 may be coupled to the plurality of traces 420, via a first programmable circuit 430 coupled between the first input/output pin 412 and the plurality of traces 420. The first programmable circuit 430 may include at least one of a demultiplexing section or a multiplexing section, similar to the first programmable circuit 130, 230, 330 described in various aspects above.

As shown in the top view of FIGS. 4B and 4C, the second die (Die 2) 442 may be coupled to a first trace 420a of the plurality of traces 420 through the second input/output pin. The third die (Die 3) 444 may be coupled to a second trace 420 b of the plurality of traces 420 through the third input/output pin. The fourth die (Die 4) 446 may be coupled to a third trace 420 c of the plurality of traces 420 through the fourth input/output pin 418.

In an aspect, a respective programmable circuit may be optionally coupled to each of the dies 442, 444, 446, to control the signal routing between the dies and the traces 420.

In the one-to-many die interconnection provided by the configurable bridge 402 according to the aspects of FIGS. 4A, 4D and 4E, the signal from one primary die 440 may be transmitted to multiple secondary dies 442, 444, 446. In other words, the primary die (Die 1) 440 may communicate with the multiple secondary dies (e.g., Die 2, Die 3, Die 4) through a single solder bump coupled to the first programmable circuit 430. The first programmable circuit 430 may encode/generate the respective subset of signals for each secondary die 442, 444, 446 using selector signals (S0, S1, S2) and a clock source (CLK) from the primary die 440 or the secondary dies 442, 444, 446, allowing one bump (for the primary die 440) to connect to multiple bumps (for the secondary dies 442, 444, 446) effectively. The signal including Data 1, Data 2, and Data 3 from the primary die (Die 1) 440 may be transmitted to their corresponding receiver, e.g., Die 2, Die 3 and Die 4, through the bridge 402.

In various aspects as shown in FIGS. 4D and 4E, the first subset of signals (Data 1) may be routed to the first trace 420a, and subsequently to the second die (Die 2) 442. The second subset of signals (Data 2) may be routed to the second trace 420b, and subsequently to the third die (Die 3) 444. The third subset of signals (Data 1, or Data 3, or both) may be routed to the third trace 420c, and subsequently to the fourth die (Die 4) 446.

In the aspect as shown in FIG. 4D, a second programmable circuit 431 may be included to couple the first trace 420 a to the second die (Die 2) 442 through the second input/output pin 414 in the bridge 402. A third programmable circuit 433 may be included to couple the second trace 420 b to the third die (Die 3) 444 through the third input/output pin 416 in the bridge 402. A fourth programmable circuit 435 may be included to couple the third trace 420c to the fourth die (Die 4) 446 through the fourth input/output pin 418 in the bridge 402. In a further aspect, the same trace may be coupled to one or more dies through the programmable circuit. For example, the second trace 420b may also be coupled to the second programmable circuit 431, such that the second subset of signals (Data 2) transmitted via the second trace 420b may also be routed to the second die (Die 2) 442. By the respective programmable circuit 431, 433, 435, the signal routing between the traces 420 and the dies 442, 444, 446 may be varied in a flexible manner.

In another aspect as shown in FIG. 4E, the dies 442, 444, 446 may be directly coupled to their respective predetermined traces, without the second programmable circuit 431, the third programmable circuit 433 and the fourth programmable circuit 435.

In various aspects as shown in FIGS. 4D and 4E, the first programmable circuit 430 may include a demultiplexing section, similar to the first programmable circuit 130, 230, 330 described in various aspects above.

In the aspects as shown in FIGS. 4D and 4E, the demultiplexing section of the first programmable circuit 430 may include three groups of programmable LUTs, flip-flops and multiplexers, to route the three subsets of signals to the first trace 420a, the second trace 420b, and the third trace 420c, respectively. In an aspect similar to FIG. 3C, the LUTs may be coupled to the multiplexed signal and the selector signals (S0, S1, S2). The flip-flops may be coupled to a clock source. The selector signals (S0, S1, S2) and the clock source may be provided by any of the dies 440, 442, 444, 446. Although three selector signals may be coupled to the LUTs in this example, it is understood that one or more selector signals may be used in other examples depending on how the LUTs have been programmed. The selection criteria that the LUT may separate and select the appropriate subset of signals may be programmable according to user need. In another aspect, the demultiplexing section may be implemented by at least a programmable LUT, a flip-flop, and a demultiplexer (not shown).

In a further aspect, the demultiplexing section may be implemented by at least a programmable LUT and a flip-flop connected to form a demultiplexing circuit. FIG. 4F shows a schematic view of circuitry interconnection of the first programmable circuit 430, similar to the circuitry interconnection of the first programmable circuit 330 shown in FIG. 3D. In the example as shown in FIG. 4F, the demultiplexing section of the first programmable circuit 430 may include a programmable LUTs and three flip-flops to route the three subsets of signals to three traces, respectively. It is understood that the demultiplexing section may be implemented in any suitable combination of circuit components or may be implemented in a processor in various aspects to perform the demultiplexing operations as described above.

In various aspects shown in FIG. 4D, each of the second programmable circuit 431, the third programmable circuit 433, and the fourth programmable circuit 435 may include a multiplexing section operable to process and route the respective subset of signals from the three traces 420a, 420b, 420c to the three dies 442, 444, 446.

In an aspect, the multiplexing section of the second programmable circuit 431, the third programmable circuit 433, and the fourth programmable circuit 435 may be implemented by at least a programmable LUT, a flip-flop, and a multiplexer, similar to the second programmable circuit 331 of FIG. 3C. In an aspect, the LUT may be coupled to the respective traces 420a, 420b, 420c. The flip-flops may be coupled to the clock source from the first die 440. In anther aspect, the multiplexing section of the second programmable circuit 431, the third programmable circuit 433, and the fourth programmable circuit 435 may be implemented by at least a programmable LUT and a flip-flop, similar to the second programmable circuit 331 of FIG. 3E. It is understood that the multiplexing section may be implemented in any suitable combination of circuit components or may be implemented in a processor in various aspects to perform the multiplexing operations as described above.

In the many-to-one die interconnection provided by the configurable bridge 402 according to the aspects of FIGS. 4G, 4H and 4I, multiple secondary dies 442, 444, 446 (e.g., Die 2, Die 3, Die 4) may communicate with the primary die 440 (Die 1) through a single solder bump coupled to the first programmable circuit 430. The first programmable circuit 430 may be managed by selector signals (S0, S1, S2) and a clock signal (CLK), to combine three signals (Data 2, Data 3, Data 4) from the multiple secondary dies 442, 444, 446 into one multiplexed signal. This may reduce the bump count down to one solder bump for the primary die 440 to receive the multiplexed singal and streamline the footprint required, as compared to a conventional structure wherein three solder bumps may be required for the primary die 440 to receive the three signals.

In various aspects as shown in FIGS. 4H and 4I, the first signal (Data 2) from the second die (Die 2) 442 may be routed to the first trace 420a. The second signal (Data 3) from the third die (Die 3) 444 may be routed to the second trace 420b. The third signal (Data 4) from the fourth die (Die 4) 446 may be routed to the third trace 420c.

In the aspect as shown in FIG. 4H, the second programmable circuit 431 may be included in the bridge 402 to couple the first trace 420 a to the second die (Die 2) 442. The third programmable circuit 433 may be included in the bridge 402 to couple the second trace 420b to the third die (Die 3) 444. The fourth programmable circuit 435 may be included in the bridge 402 to couple the third trace 420 b to the fourth die (Die 4) 446.

In another aspect as shown in FIG. 4I, the dies 442, 444, 446 may be directly coupled to their respective predetermined traces, without the second programmable circuit 431, the third programmable circuit 433 and the fourth programmable circuit 435.

In various aspects as shown in FIGS. 4H and 4I, the first programmable circuit 430 may include a multiplexing section, similar to the multiplexing section of the second programmable circuit 331 of FIG. 3C or FIG. 3E described in various aspects above.

In the aspects as shown in FIGS. 4H and 4I, the multiplexing section of the first programmable circuit 430 may include a group of a programmable LUT, a flip-flop and a multiplexer, to combine the three signals (Data 2, Data 3, Data 4) received from the first trace 420a, the second trace 420b and the third trace 420c into one multiplexed signal for routing to the first die 440 (Die 1). In an aspect similar to FIG. 3C, the LUT may be coupled to the three signals (Data 2, Data 3, Data 4) and the selector signals (S0, S1, S2). The flip-flop may be coupled to the clock source. It is understood that the multiplexing section may be implemented in any suitable combination of circuit components (e.g., by a combination of at least a programmable LUT and a flip-flop similar to the circuitry shown in FIG. 3E), or may be implemented in a processor in various aspects to perform the multiplexing operations as described above.

In various aspects shown in FIG. 4H, each of the second programmable circuit 431, the third programmable circuit 433, and the fourth programmable circuit 435 may include a demultiplexing section operable to process and route the respective signals from the three dies 442, 444, 446 to the three traces 420a, 420b, 420c.

In an aspect, the demultiplexing section of the second programmable circuit 431, the third programmable circuit 433, and the fourth programmable circuit 435 may be implemented by at least a programmable LUT, a flip-flop, and a multiplexer, similar to the first programmable circuit 330 of FIG. 3G. In an aspect, the LUT may be coupled to the respective data signals (Data 2, Data 3, Data 4). The flip-flop may be coupled to the clock source from the first die 440. It is understood that the demultiplexing section may be implemented in any suitable combination of circuit components (e.g., by a combination of at least a programmable LUT and a flip-flop similar to the circuitry shown in FIG. 3D), or may be implemented in a processor in various aspects to perform the demultiplexing operations as described above.

The present disclosure may provide a semiconductor package with a configurable bridge for improved reliability and device miniaturization. The configurable bridge having at least a programmable circuit according to various aspects may be applied in one-to-one die interconnection for reduced solder bump count or defect remedy. The configurable bridge according to various aspects may further be applied to one-to-many and many-to-one die interconnection to control or configure the signal routing among a plurality of dies.

FIG. 5 shows a flowchart 500 illustrating a method of forming a device, such as the device 100, 200, 250, 300, 400 of FIGS. 1A-1B, 2A-2B, 3A-3G and 4A-4I, according to an aspect of the present disclosure. Various aspects described with reference to FIGS. 1A-1C, 2A-2B, 3A-3G and 4A-4I may be similarly applied for the method of FIG. 5.

At 502, the method may include providing a bridge having a first input/output pin and a second input/output pin.

At 504, the method may include forming a plurality of traces extending horizontally between the first input/output pin and the second input/output pin, and coupling the second input/output pin to a predetermined one or more of the plurality of traces.

At 506, the method may include coupling a first programmable circuit between the first input/output pin and the plurality of traces, wherein the first programmable circuit may include at least one of a demultiplexing section or a multiplexing section. The demultiplexing section may be operable to demultiplex a multiplexed signal received from the first input/output pin into at least one subset of signals, and route a respective subset of signals to a corresponding one of the plurality of traces. The multiplexing section may be operable to multiplex the at least one subset of signals received from the plurality of traces into the multiplexed signal, and route the multiplexed signal to the first input/output pin.

It will be understood that the operations described above relating to FIG. 5 are not limited to this particular order. Any suitable, modified order of operations may be used.

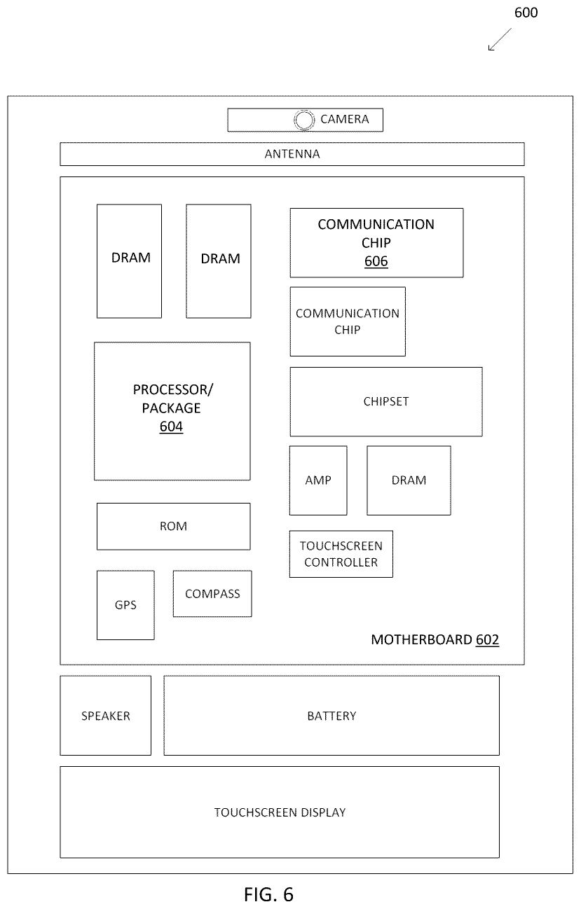

Aspects of the present disclosure may be implemented into a system using any suitable hardware and/or software. FIG. 6 schematically illustrates a computing device 600 that may include a device 100, 200, 250, 300, 400 as described herein, in accordance with some aspects. The computing device 600 may house a board such as a motherboard 602. The motherboard 602 may include several components, including but not limited to a processor 604, according to the present disclosure, and at least one communication chip 606. The processor 604, which may have a device according to the present disclosure, may be physically and electrically coupled to the motherboard 602. In some implementations, the at least one communication chip 606 may also be physically and electrically coupled to the motherboard 602. In further implementations, the communication chip 606 may be part of the processor 604.

Depending on its applications, the computing device 600 may include other components that may or may not be physically and electrically coupled to the motherboard 602. These other components may include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 606 may implement any of several wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP 2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 606 may also operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other aspects.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

In various implementations, the computing device 600 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In an aspect, the computing device 600 may be a mobile computing device. In further implementations, the computing device 600 may be any other electronic device that processes data.

### EXAMPLES

Example 1 may include a device including a bridge having a first input/output pin and a second input/output pin; a plurality of traces extending horizontally between the first input/output pin and the second input/output pin, the second input/output pin being coupled to a predetermined one or more of the plurality of traces; and a first programmable circuit coupled between the first input/output pin and the plurality of traces. The first programmable circuit may include at least one of a demultiplexing section or a multiplexing section; wherein the demultiplexing section may be operable to demultiplex a multiplexed signal received from the first input/output pin into at least one subset of signals, and route a respective subset of signals to a corresponding one of the plurality of traces; and wherein the multiplexing section may be operable to multiplex the at least one subset of signals received from the plurality of traces into the multiplexed signal, and route the multiplexed signal to the first input/output pin.

Example 2 may include the subject matter of Example 1, wherein the first programmable circuit may include a programmable look up table and a flip-flop.

Example 3 may include the subject matter of Example 1, wherein the first programmable circuit may include a programmable look up table, a flip-flop, and at least one of a multiplexer or a demultiplexer.

Example 4 may include the subject matter of any one of Example 1 to 3, further including a first die coupled to the first input/output pin through a first solder bump, wherein the first input/output pin and the first solder bump may be configured for transmission of the multiplexed signal between the first die and the first programmable circuit.

Example 5 may include the subject matter of any one of Example 1 to 4, further including a second die coupled to the second input/output pin through a second solder bump, wherein the second input/output pin and the second solder bump may be configured for transmission of the respective subset of signals between the second die and the first programmable circuit.

Example 6 may include the subject matter of Example 5, wherein the plurality of traces may include a first trace and a second trace, and wherein the second input/output pin may be coupled to the first trace and the second trace.

Example 7 may include the subject matter of Example 6, further including a second programmable circuit coupling the second input/output pin to the first trace and the second trace; wherein the second programmable circuit may include at least one of a demultiplexing section or a multiplexing section. The multiplexing section may be operable to multiplex a first subset of signals from the first trace and a second subset of signals from the second trace into a re-multiplexed signal, and route the re-multiplexed signal to the second input/output pin. The demultiplexing section may be operable to demultiplex the re-multiplexed signal received from the second die into the first subset of signals and the second subset of signals, and route the first subset of signals and the second subset of signals to the first trace and the second trace, respectively.

Example 8 may include the subject matter of any one of Example 1 to 7, further including a third input/output pin coupled to another predetermined one or more of the plurality of traces; wherein the plurality of traces may include a first trace and a second trace; and wherein the second input/output pin may be coupled to the first trace, and the third input/output pin may be coupled to the second trace.

Example 9 may include the subject matter of Example 8, further including a third die coupled to the third input/output pin through a third solder bump; wherein the third input/output pin and the third solder bump may be configured for transmission of the respective subset of signals between the third die and the first programmable circuit.

Example 10 may include the subject matter of any one of Example 1 to 9, wherein the multiplexed signal may include one or more data signals multiplexed based on time division multiplexing; and wherein the at least one subset of signals may include at least one of the data signals.

Example 11 may include the subject matter of any one of Example 1 to 10, wherein the bridge may include a bridge substrate, and a redistribution layer on the bridge substrate.

Example 12 may include the subject matter of Example 11, wherein the first programmable circuit may be arranged within the redistribution layer.

Example 13 may include the subject matter of Example 11, wherein the first programmable circuit may be arranged at least partially in the bridge substrate.

Example 14 may include a semiconductor package. The semiconductor package may include a substrate; and a bridge at least partially embedded in the substrate. The bridge may include a first input/output pin; a second input/output pin; a plurality of traces extending horizontally between the first input/output pin and the second input/output pin, the second input/output pin being coupled to a predetermined one or more of the plurality of traces; a first programmable circuit coupled between the first input/output pin and the plurality of traces; a first die on the substrate and coupled to the first input/output pin; and a second die on the substrate and coupled to the second input/output pin. The first programmable circuit may include at least one of a demultiplexing section or a multiplexing section; wherein the demultiplexing section may be operable to demultiplex a multiplexed signal received from the first input/output pin into at least one subset of signals, and route a respective subset of signals to a corresponding one of the plurality of traces; and wherein the multiplexing section may be operable to multiplex the at least one subset of signals received from the plurality of traces into the multiplexed signal, and route the multiplexed signal to the first input/output pin.

Example 15 may include the subject matter of Example 14, wherein the first programmable circuit may include a programmable look up table and a flip-flop.

Example 16 may include the subject matter of Example 14, wherein the first programmable circuit may include a programmable look up table, a flip-flop, and at least one of a multiplexer or a demultiplexer.

Example 17 may include the subject matter of any one of Example 14 to 16, further including a third input/output pin in the bridge and coupled to another predetermined one or more of the plurality of traces, and a third die on the substrate and coupled to the third input/output pin

Example 18 may include the subject matter of any one of Example 14 to 17, further including a second programmable circuit coupling the second input/output pin to the predetermined one or more of the plurality of traces; wherein the second programmable circuit may include at least one of a demultiplexing section or a multiplexing section. The multiplexing section may be operable to multiplex the respective subset of signals from the predetermined one or more of the plurality of traces into a re-multiplexed signal, and route the re-multiplexed signal to the second input/output pin. The demultiplexing section may be operable to demultiplex the re-multiplexed signal received from the second die into the respective subset of signals, and route the respective subset of signals to the predetermined one or more of the plurality of traces.

Example 19 may include a method of forming a device. The method may include providing a bridge having a first input/output pin and a second input/output pin; forming a plurality of traces extending horizontally between the first input/output pin and the second input/output pin, and coupling the second input/output pin to a predetermined one or more of the plurality of traces; and coupling a first programmable circuit between the first input/output pin and the plurality of traces. The first programmable circuit may include at least one of a demultiplexing section or a multiplexing section; wherein the demultiplexing section may be operable to demultiplex a multiplexed signal received from the first input/output pin into at least one subset of signals, and route a respective subset of signals to a corresponding one of the plurality of traces; and wherein the multiplexing section may be operable to multiplex the at least one subset of signals received from the plurality of traces into the multiplexed signal, and route the multiplexed signal to the first input/output pin.

Example 20 may include the subject matter of Example 19, further including coupling a second programmable circuit between the second input/output pin and the predetermined one or more of the plurality of traces; wherein the second programmable circuit may include at least one of a demultiplexing section or a multiplexing section. The multiplexing section may be operable to multiplex the respective subset of signals from the predetermined one or more of the plurality of traces into a re-multiplexed signal, and route the re-multiplexed signal to the second input/output pin. The demultiplexing section may be operable to demultiplex the re-multiplexed signal into the respective subset of signals, and route the respective subset of signals to the predetermined one or more of the plurality of traces.

In a further example, any one or more of examples 1 to 20 may be combined.

These and other advantages and features of the aspects herein disclosed will be apparent through reference to the above description and the accompanying drawings. Furthermore, it is to be understood that the features of the various aspects described herein are not mutually exclusive and can exist in various combinations and permutations.

It will be understood that any property described herein for a specific device may also hold for any device described herein. It will also be understood that any property described herein for a specific method may hold for any of the methods described herein. Furthermore, it will be understood that for any device or method described herein, not necessarily all the components or operations described will be enclosed in the device or method, but only some (but not all) components or operations may be enclosed.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words, coupling without direct contact) may be provided.

While the present disclosure has been particularly shown and described with reference to specific aspects, it should be understood by those skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a bridge having a first input/output pin and a second input/output pin;
a plurality of traces extending horizontally between the first input/output pin and the second input/output pin, wherein the second input/output pin is coupled to a predetermined one or more of the plurality of traces; and
a first programmable circuit coupled between the first input/output pin and the plurality of traces, and comprising at least one of a demultiplexing section or a multiplexing section;
wherein the demultiplexing section is operable to demultiplex a multiplexed signal received from the first input/output pin into at least one subset of signals, and route a respective subset of signals to a corresponding one of the plurality of traces; and wherein the multiplexing section is operable to multiplex the at least one subset of signals received from the plurality of traces into the multiplexed signal, and route the multiplexed signal to the first input/output pin.

2. The device of claim 1, wherein the first programmable circuit comprises a programmable look up table and a flip-flop.

3. The device of claim 1, wherein the first programmable circuit comprises a programmable look up table, a flip-flop, and at least one of a multiplexer or a demultiplexer.

4. The device of claim 1, further comprising a first die coupled to the first input/output pin through a first solder bump, wherein the first input/output pin and the first solder bump are configured for transmission of the multiplexed signal between the first die and the first programmable circuit.

5. The device of claim 1, further comprising a second die coupled to the second input/output pin through a second solder bump, wherein the second input/output pin and the second solder bump are configured for transmission of the respective subset of signals between the second die and the first programmable circuit.

6. The device of claim 5, wherein the plurality of traces comprises a first trace and a second trace, and wherein the second input/output pin is coupled to the first trace and the second trace.

7. The device of claim 6, further comprising a second programmable circuit coupling the second input/output pin to the first trace and the second trace; wherein the second programmable circuit comprises at least one of a demultiplexing section or a multiplexing section;
wherein the multiplexing section is operable to multiplex a first subset of signals from the first trace and a second subset of signals from the second trace into a re-multiplexed signal, and route the re-multiplexed signal to the second input/output pin;
wherein the demultiplexing section is operable to demultiplex the re-multiplexed signal received from the second die into the first subset of signals and the second subset of signals, and route the first subset of signals and the second subset of signals to the first trace and the second trace, respectively.

8. The device of claim 1, further comprising a third input/output pin coupled to another predetermined one or more of the plurality of traces;
wherein the plurality of traces comprises a first trace and a second trace; and
wherein the second input/output pin is coupled to the first trace, and the third input/output pin is coupled to the second trace.

9. The device of claim 8, further comprising a third die coupled to the third input/output pin through a third solder bump; wherein the third input/output pin and the third solder bump are configured for transmission of the respective subset of signals between the third die and the first programmable circuit.

10. The device of claim 1, wherein the multiplexed signal comprises one or more data signals multiplexed based on time division multiplexing; and wherein the at least one subset of signals comprises at least one of the data signals.

11. The device of claim 1, wherein the bridge comprises a bridge substrate, and a redistribution layer on the bridge substrate.

12. The device of claim 11, wherein the first programmable circuit is arranged within the redistribution layer.

13. The device of claim 11, wherein the first programmable circuit is arranged at least partially in the bridge substrate.

14. A semiconductor package comprising:
a substrate□
a bridge at least partially embedded in the substrate, comprising:
a first input/output pin and a second input/output pin;
a plurality of traces extending horizontally between the first input/output pin and the second input/output pin, wherein the second input/output pin is coupled to a predetermined one or more of the plurality of traces;
a first programmable circuit coupled between the first input/output pin and the plurality of traces, and comprising at least one of a demultiplexing section or a multiplexing section;
wherein the demultiplexing section is operable to demultiplex a multiplexed signal received from the first input/output pin into at least one subset of signals, and route a respective subset of signals to a corresponding one of the plurality of traces; and wherein the multiplexing section is operable to multiplex the at least one subset of signals received from the plurality of traces into the multiplexed signal, and route the multiplexed signal to the first input/output pin;
a first die on the substrate and coupled to the first input/output pin; and
a second die on the substrate and coupled to the second input/output pin.

15. The semiconductor package of claim 14, wherein the first programmable circuit comprises a programmable look up table and a flip-flop.

16. The semiconductor package of claim 14, wherein the first programmable circuit comprises a programmable look up table, a flip-flop, and at least one of a multiplexer or a demultiplexer.

17. The semiconductor package of claim 14, further comprising a third input/output pin in the bridge and coupled to another predetermined one or more of the plurality of traces, and a third die on the substrate and coupled to the third input/output pin.

18. The semiconductor package of claim 14, further comprising a second programmable circuit coupling the second input/output pin to the predetermined one or more of the plurality of traces; wherein the second programmable circuit comprises at least one of a demultiplexing section or a multiplexing section;
wherein the multiplexing section is operable to multiplex the respective subset of signals from the predetermined one or more of the plurality of traces into a re-multiplexed signal, and route the re-multiplexed signal to the second input/output pin;
wherein the demultiplexing section is operable to demultiplex the re-multiplexed signal received from the second die into the respective subset of signals, and route the respective subset of signals to the predetermined one or more of the plurality of traces.

19. A method comprising:
providing a bridge having a first input/output pin and a second input/output pin;
forming a plurality of traces extending horizontally between the first input/output pin and the second input/output pin, and coupling the second input/output pin to a predetermined one or more of the plurality of traces; and
coupling a first programmable circuit between the first input/output pin and the plurality of traces, wherein the first programmable circuit comprises at least one of a demultiplexing section or a multiplexing section;
wherein the demultiplexing section is operable to demultiplex a multiplexed signal received from the first input/output pin into at least one subset of signals, and route a respective subset of signals to a corresponding one of the plurality of traces; and wherein the multiplexing section is operable to multiplex the at least one subset of signals received from the plurality of traces into the multiplexed signal, and route the multiplexed signal to the first input/output pin.

20. The method of claim 19, further comprising:
coupling a second programmable circuit between the second input/output pin and the predetermined one or more of the plurality of traces; wherein the second programmable circuit comprises at least one of a demultiplexing section or a multiplexing section;
wherein the multiplexing section is operable to multiplex the respective subset of signals from the predetermined one or more of the plurality of traces into a re-multiplexed signal, and route the re-multiplexed signal to the second input/output pin;
wherein the demultiplexing section is operable to demultiplex the re-multiplexed signal into the respective subset of signals, and route the respective subset of signals to the predetermined one or more of the plurality of traces.
